(19) United States
(12) Patent Application Publication
(10) Pub. No.: US 2007/0057820 A1
(43) Pub. Date: Mar. 15, 2007

(54) Retaining device for controller of game machine

(76) Inventor: Barbara Pao, Taichung (TW)

Correspondence Address: Barbara PAO, 235 Chung-Ho, Box 8-24, Taipei, TW

(21) Appl. No.: 11/204,243

(22) Filed: Aug. 16, 2005

(51) Int. Cl. H03M 11/00

(52) U.S. Cl. 341/22

(57) ABSTRACT

A retaining device for a controller of a game machine comprises a body having a concave center portion; a periphery ring portion arranged around the concave portion; the ring portion being formed as a combining portion; the body has a shape like a hat; a penetrating hole formed at the concave portion of the body for receiving a cable of a main frame of a game machine; a slot being formed in the concave portion; a shape supporter received in the slot; the supporter having a wide head and a narrow extending portion; one end of the extending portion far away from the head having an inserting recess; and a stop unit capable of receiving in the insertion recess of the extending portion; the stop unit having a distance from the body for locating; and a space is defined as a receiving portion.

### FIELD OF THE INVENTION

The present invention relates to retainer devices, and particularly to a retaining device for a controller of a game machine, wherein the main frame of a game machine and controller can be arranged in order so that the user can arrange them conveniently and easily with a beautiful outlook.

### BACKGROUND OF THE INVENTION

Currently, game machines need controllers for controlling, the operations in the gaming process. These kinds of game machines are such as NINTENDO-64, SATRUN (SEGA), PLAY-STATION (PS), X-BOX, etc., which are main trends in the game machine market.

Generally, the main frame 100 of a game machine has a controller 102 which is connected to the main frame 100 through a cable 104. They a re placed in a cabinet 40 or upon an upper surface of the cabinet 40. If the user desires to play the game, the user must take the controller 102 out of the cabinet 40 and then to take the controller 102 to a farther distance. This is because the controller 102 is generally located at a farther distance from the main frame 100 of the game machine to avoid that the user is too close the main frame 100 so as to hurt his (or her) eyes. After the game is over, the user must take the controller 102 to the cabinet 40. The operation is very inconvenient. If the main frame 100 and the controller 102 are placed in a cabinet, the user must open and close the doorplates of the cabinet 40 many time. Thereby in the prior art design, the controller 102 is not properly located and thus they are arranged disorderly.

Thereby there is an eager demand for a novel design which can improve these defects in the prior art.

### SUMMARY OF THE INVENTION

Accordingly, the primary object of the present invention is to provide a retaining device for a controller of a game machine, wherein the main frame of a game machine and controller can be arranged in order so that the user can arrange them conveniently and easily with a beautiful outlook.

To achieve above objects, the present invention provides a retaining device for a controller of a game machine. The retaining device comprises a body having a concave center portion; a periphery ring portion arranged around the concave portion; the ring portion being formed as a combining portion; the body having a shape like a hat; a penetrating hole formed at the concave portion of the body for receiving a cable of a main frame of a game machine; a slot being formed in the concave portion; a shape supporter received in the slot; the supporter having a wide head and a narrow extending portion; one end of the extending portion far away from the head having an inserting recess; and a stop unit capable of receiving in the insertion recess of the extending portion; the stop unit having a distance from the body for locating; a space is defined as a receiving portion.

The various objects and advantages of the present invention will be more readily understood from the following detailed description when read in conjunction with the appended drawing.

### BRIEF DESCRIPTION OF THE DRAWINGS

FIG. 1 is an exploded schematic view of the retaining device of the present invention.

FIG. 2 is a schematic perspective view of the retaining device of the present invention.

FIG. 3 is a schematic perspective view of the present invention, where the present invention is assembled to a cabinet.

FIG. 4 is partial schematic cross sectional view showing that the retaining device of the present invention is combined to a cabinet.

FIG. 5 is a schematic view showing that controllers are received in the receiving portion of the present invention.

FIG. 6 is a schematic view showing the operation of the present invention.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

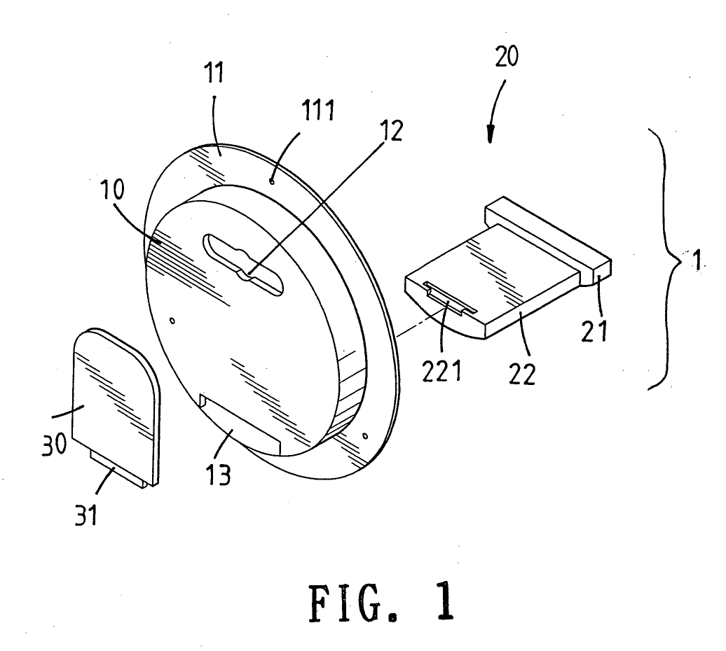

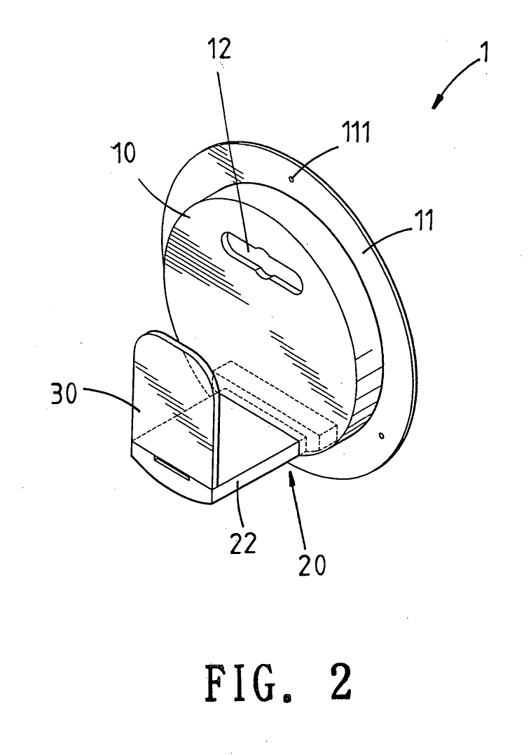

Referring portion to FIGS. 1, 2 and 5, in the present invention, the retaining unit 1 has a round shape, however in the present invention, the shape of the retaining unit 1 is not confined to be round shapes, other shapes are permissible.

The retaining unit 1 has the following elements.

A body 10 is a round disk with a concave center portion. A ring portion 11 is arranged around the concave portion. The ring portion 11 is formed as a combining portion 11. A plurality of holes 111 are formed on the ring portion 11. Thereby the body 10 has a shape like a hat.

A penetrating hole 12 is formed at the concave portion of the body 10 for receiving a cable 104 of a main frame 100 of a game machine. A long slot 13 is formed at an edge portion of the concave portion.

A T shape supporter 20 is received in the slot 13. The supporter 20 has a wide head 21 and a narrow extending portion 22. The head 21 and the extending portion 22 may be separated. A width of the extending portion 22 is equal to or slightly smaller than that of the slot 13 so that the extending portion 22 can pass through the slot 13 easily without vibration. A width of the head 21 is larger than that of the slot 13. Thereby the supporter 20 is confined. One end of the extending portion 22 far away from the head 21 has an inserting recess 221 for receiving vertically a stop unit 30.

The stop unit 30 has a sheet with a predetermined thickness. A width of the stop unit 30 is equal to that of the extending portion 22. A lower side of the stop unit 30 is extended with a connecting sheet which has a width corresponding to the width of the insertion recess 221 of the extending portion 22. The connecting sheet is inserted into the insertion recess 221 so as to fix the stop unit 30 to the extending portion 22 of the supporter 20. Thereby the stop unit 30 has a distance from the body 10 for locating a controller 102 of a main frame 100 of a game machine. The space is defined as a receiving portion A. Thereby the structure of the present invention is formed.

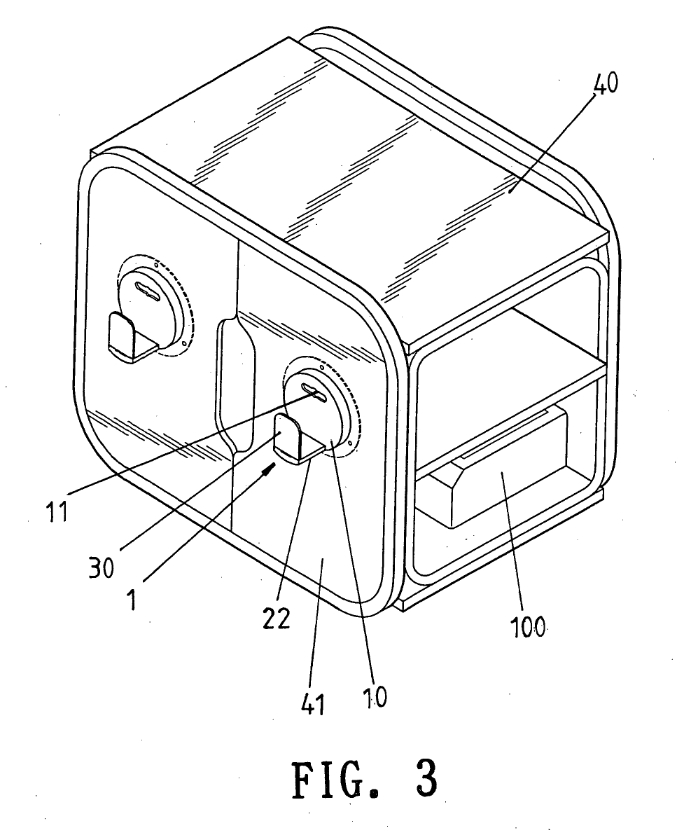

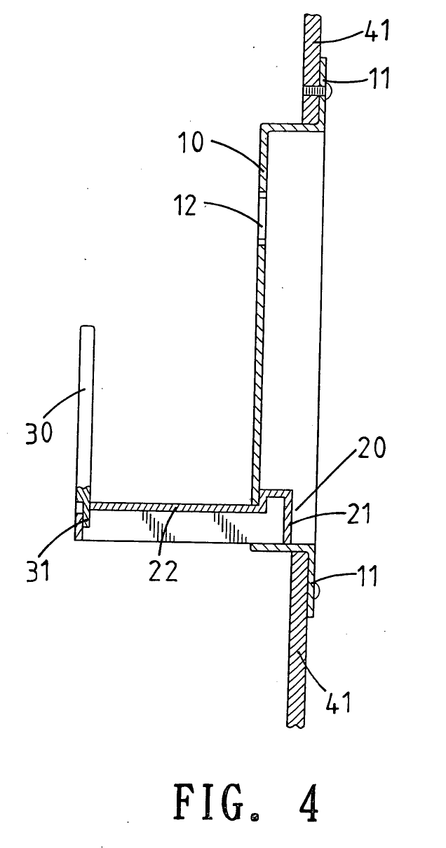

In use of the present invention, it is preferred that the present invention is used with a cabinet. Referring portion to FIGS. 3 and 4, a cabinet 40 has two doorplates 41 which can be opened outwards. Each doorplate 41 is formed with a round hole corresponding to the retaining unit 1 of the present invention. The retaining unit 1 passes through the doorplate hole from an inner side of the cabinet 40 to the outer side. Screws passes through the small holes 111 of the combining portion 11 of the body 10 so that the retaining unit 1 is fixed to the cabinet 40.

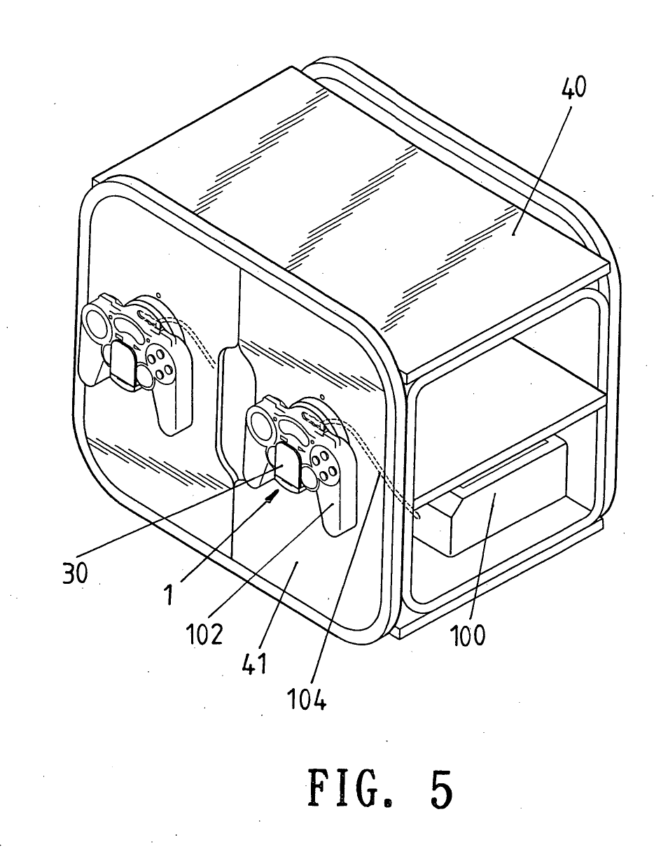

Referring portion to FIG. 5, the main frame 100 of a game machine is placed at an interior of the cabinet 40. The signal cabinet 40 of the controller 102 passes through the penetrating hole 12 of the body 10 to be connected to the main frame 100 of a game machine. Thereby the cabinet 40 may be retained in order. The controller 102 will not expose out to have a bad outlook or to hinder the actions of users or other people. The controller 102 can be placed in the receiving portion A. Thereby, the controller 102 can be taken out or placed in the receiving portion A rapidly and easily.

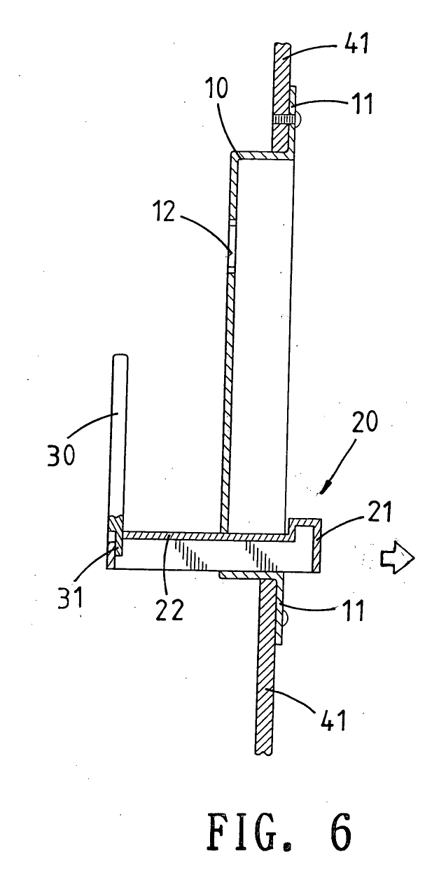

Referring portion to FIG. 6, characteristics of the present invention are that the extending portion 22 is movably inserted into the body 10. A width of the extending portion 22 is adjustable by moving the extending portion 22 to move closer or far away from the body 10 to control the size of the receiving portion A. Thus the size of the receiving portion A can be suitable for various controllers 102 and the controller 102 is firmly retained not to fall out or vibrate.

As illustrated in FIG. 6, the body 10 of the present invention has a U shape cross section, the concave portion has a predetermined width so that the extending portion 22 can be retained to the wall of the concave portion firmly.

Furthermore, in the present invention, the width of the extending portion 22 may be equal to or slightly smaller than the width of the slot 13. When the extending portion 22 is pulled to a predetermined position, the extending portion 22 can be engaged tightly at edges of the slot 13. Thus the extending portion 22 will not vibrate.

The present invention is thus described, and it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A retaining device for a controller of a game machine comprising:
a body having a concave center portion; a periphery ring portion arranged around the concave portion; the ring portion being formed as a combining portion; the body has a shape like a hat;
a penetrating hole formed at the concave portion of the body for receiving a cable of a main frame of a game machine; a slot being formed in the concave portion;
a shape supporter received in the slot; the supporter having a wide head and a narrow extending portion; one end of the extending portion far away from the head having an inserting recess; and
a stop unit capable of receiving in the insertion recess of the extending portion; the stop unit having a distance from the body; a space between the stop unit and the body being defined as a receiving portion.

2. The retaining device for a controller of a game machine as claimed in claim 1, wherein a plurality of holes are formed on the ring portion.

3. The retaining device for a controller of a game machine as claimed in claim 1, wherein the head and the extending portion are integrally formed.

4. The retaining device for a controller of a game machine as claimed in claim 1, wherein the head and the extending portion are made individually.

5. The retaining device for a controller of a game machine as claimed in claim 1, wherein a width of the extending portion is equal to or slightly smaller than that of the slot so that the extending portion can pass through the slot without vibration.

6. The retaining device for a controller of a game machine as claimed in claim 1, wherein a width of the head is larger than that of the slot; thereby the supporter is confined.

7. The retaining device for a controller of a game machine as claimed in claim 1, wherein a lower side of the stop unit is extended with a connecting sheet which has a width corresponding to the width of the insertion recess of the extending portion; and the connecting sheet is inserted into the insertion recess so as to fix the stop unit to the extending portion of the supporter.
